(19) United States
(12) Patent Application Publication
(10) Pub. No.: US 2007/0051986 A1
(43) Pub. Date: Mar. 8, 2007

(54) Image sensor and method of fabricating the same

(76) Inventor: Kim Sang Sik, Suwon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/506,471

(22) Filed: Aug. 18, 2006

(30) Foreign Application Priority Data
Aug. 19, 2005 (KR) 10-2005-0076151

(51) Int. Cl. H01L 27/148

(52) U.S. Cl. 257/232

(57) ABSTRACT

An image sensor is provided. The image sensor includes a substrate having a plurality of cell regions, photodiodes formed in the cell regions of the substrate an antireflection layer, a color filter layer, a planarization layer, and a plurality of microlenses. The antireflection layer is formed above the substrate including the photodiodes and incorporates at least two insulating layers with different refractive indexes. The color filter layer is formed on the antireflection layer and corresponds to the photodiodes of the cell regions. The planarization layer is formed on the color filter layer. The plurality of microlenses is formed on the planarization layer and correspond to the photodiodes of the cell regions.

### RELATED APPLICATION

This application claims the benefit under 35 U.S.C. §119(e) of Korean Patent Application Number 10-2005-0076151 filed Aug. 19, 2005, which is incorporated herein by reference in its entirety.

### FIELD OF THE INVENTION

The present invention relates to an image sensor, and more particularly, to an image sensor and a method of fabricating the same, capable of minimizing a light loss caused by an incident angle of light.

### BACKGROUND OF THE INVENTION

Generally, an image sensor is a semiconductor device that converts an optical image into an electrical signal. In a charge coupled device (CCD), metal-oxide-semiconductor (MOS) capacitors are very closely located to one another and charge carriers are stored in the capacitors and transmitted from the capacitors. In a complementary MOS (CMOS) image sensor, a switching method is employed using CMOS technology by forming MOS transistors in numbers as many as the number of pixels, and using a control circuit and a signal processing circuit as peripheral circuits and sequentially detecting an output using the MOS transistors.

In fabrication of various image sensors, efforts such as a condensing technology have been made to improve the photosensitivity of the image sensors. For example, the CMOS image sensor includes photodiodes 101 for detecting light and converting the detected light into an electric signal, and a CMOS logic circuit processing the converted electrical signal to provide corresponding data. In order to improve the photosensitivity of the CMOS image sensor, an effort has been made to increase the ratio (generally called “the fill factor”) of the area of the photodiodes to the overall area of the image sensor. However, the logic circuit cannot be simply removed. Thus, there is a limitation in such an effort made with a limited area. Accordingly, many condensing technologies for changing a path of light incident to other regions outside a light detecting section to the light detecting section have been studied. For example, a microlens 105 may be formed on a color filter to condense light to a light detecting region.

Hereinafter, a related art image sensor with microlenses will now be described with reference to the accompanying drawings.

FIG. 1 is a sectional view of an image sensor with microlenses according to the prior art.

Referring to FIG. 1, the image sensor with the microlenses 105 includes a substrate 100 having a plurality of cell regions with photodiodes 101 formed therein, an insulating layer 102 formed on an entire surface of the substrate 100 including the photodiodes 101, a color filter layer 103 formed on the insulating layer 102 to correspond to the photodiodes 101 of the cell regions, a planarization layer 104 formed on an entire surface of the substrate 100 including the color filter layer 103, a plurality of microlenses 105 formed on the planarization layer 104 to correspond to the photodiodes 101 of the cell regions, and an objective lens 106 disposed above the microlenses 105.

Light passing through the objective lens 106 is incident onto the plurality of microlenses 105. For light incident onto one of the microlenses that is located at a central portion of the image sensor at an angle of approximately 90°, the light is incident almost perpendicularly to the insulating layer 102. Accordingly, the light, being substantially non-reflected, passes through the insulating layer 102, and is provided to the photodiodes 101. That is, the light passing through the microlens 105 located at the central portion is provided to the photodiodes 101 almost without a loss.

However, for light incident onto the microlens 105 located far from the central portion of the image sensor, the light is incident at an acute angle. In particular, the farther the microlens is from the central portion, the smaller the incident angle. For example, light is incident at an angle of approximately 30° to the microlens 105 that is located at an edge portion of the image sensor. Here, light passing through the microlens 105 located at the edge portion of the image sensor and having the smaller incident angle reaches the insulating layer 102 at the lower portion and is easily reflected by the insulating layer 102. Therefore, the light passing through the microlens 105 located at the edge portion of the image sensor is not fully provided to the photodiodes 101. That is, the amount of light that is provided to the photodiodes from the microlens 105 located at the edge portion of the image sensor is greatly reduced.

Therefore, the cell regions of the edge portion of the image sensor cannot properly display corresponding original images.

### SUMMARY OF THE INVENTION

Accordingly, the present invention is directed to an image sensor and a method of fabricating the same that addresses and/or substantially obviates one or more problems, limitations, and/or disadvantages of the prior art.

An object of the present invention is to provide an image sensor and a method of fabricating the same, capable of increasing a condensing efficiency of light by forming at least two insulating layers having different refractive indexes, respectively, between a substrate, including photodiodes, and a color filter layer so as to minimize reflectance.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided an image sensor including: a substrate having a plurality of cell regions; photodiodes formed in the cell regions of the substrate; an antireflection layer formed on an entire surface of the substrate in which the photodiodes are formed and including at least two insulating layers with different refractive indexes, respectively; a color filter layer formed on the antireflection layer to correspond to the photodiodes of the cell regions; a planarization layer formed on the color filter layer; and a plurality of microlenses formed on the planarization layer to correspond to the photodiodes of the cell regions.

In another aspect of the present invention, there is provided a method of fabricating an image sensor, the method including: preparing a substrate having a plurality of cell regions; forming photodiodes in each of the cell regions of the substrate; forming an antireflection layer including at least two insulating layers with different refractive indexes, respectively on an entire surface of the substrate in which the photodiodes are formed; forming a color filter layer on the antireflection layer to correspond to the photodiodes of the cell regions; forming a planarization layer on the color filter layer; and forming a plurality of microlenses on the planarization layer to correspond to the photodiodes of the cell regions.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view of an image sensor with microlens according to the prior art.

FIG. 2 is a sectional view of an image sensor according to an embodiment of the present invention.

FIG. 3 is a sectional view showing another embodiment of an antireflection layer.

FIGS. 4A to 4C are graphs showing the reflectance based on the thickness of an antireflection layer.

FIG. 5 is a view showing a difference in the refractive index based on the wavelength incident to a microlens.

FIGS. 6A and 6B show general behavior of a light ray as it travels through various media.

FIG. 7 is a view showing the output difference based on the position of a photodiode of an image sensor.

FIGS. 8A to 8E are sectional views showing a method of forming an image sensor according to an embodiment of the present invention.

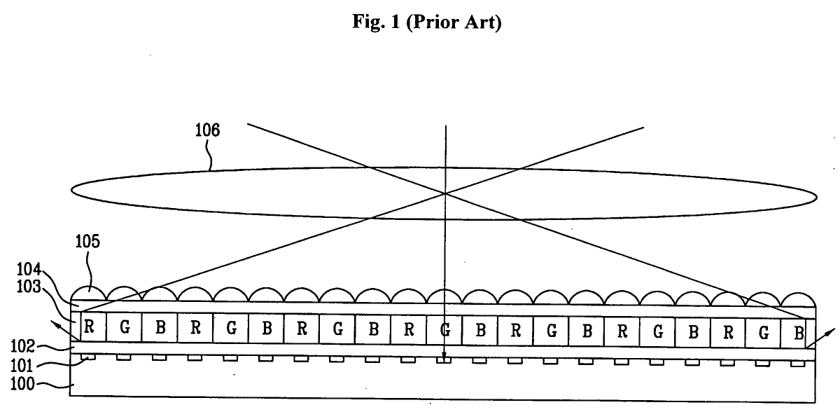

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

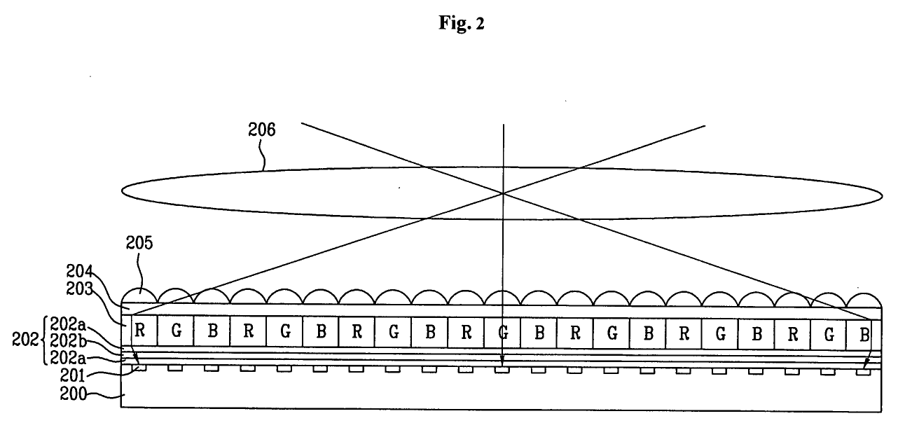

FIG. 2 is a sectional view of an image sensor according to an embodiment of the present invention.

Referring to FIG. 2, the image sensor according to an embodiment of the present invention includes a substrate 200 having a plurality of cell regions, photodiodes 201 formed in the cell regions of the substrate 200, an antireflection layer 202 that is formed above the substrate 200 including the photodiodes 201, a color filter layer 203 formed on the antireflection layer 202 to correspond to the photodiodes 201 of the cell regions, a planarization layer 204 formed on the color filter layer 203, and a plurality of microlenses 205 formed on the planarization layer 204 to correspond to the photodiodes 201 of the cell regions. In a further embodiment, an objective lens 206 can be formed above the microlenses 205.

The antireflection layer 202 can have at least two insulating layer types with different refractive indexes, respectively. In a specific embodiment, the antireflection layer 202 can incorporate three insulating layers: two first-type insulating layers 202a and one second-type insulating layer 202b. One of the two first-type insulating layers 202a can be formed on the substrate 200 in which the photodiodes 201 are formed, and the second-type insulating layer 202b can formed on the first insulating layer 202a. The other first-type insulating layer 202a can be formed on the second insulating layer 202b. That is, the second-type insulating layer 202b can be located between the two first-type insulating layers 202a.

In one embodiment, the first-type insulating layers 202a can have a larger refractive index than that of the second-type insulating layer 202b.

In operation, light is incident the antireflection layer 202 through the objective lens 206 and the microlenses 205. Because the first-type insulating layers 202a and the second-type insulating layer 202b included in the antireflection layer 202 have different refractive indexes, the light can be substantially prevented from reflecting off interfaces between the insulating layers 202a and 202b.

In a further embodiment, the antireflection layer 202 can be formed of three or more insulating layers.

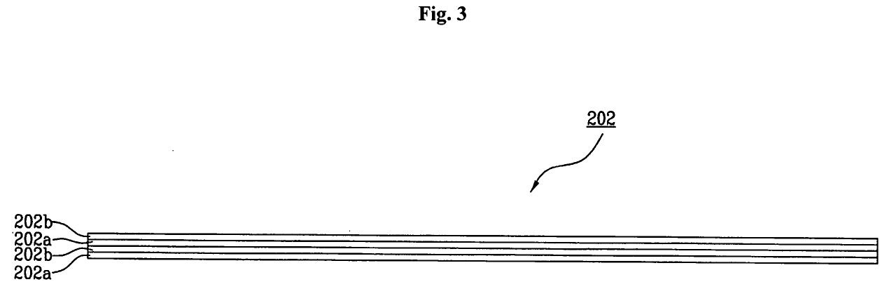

FIG. 3 is a sectional view showing another structure for the antireflection layer shown in FIG. 2.

Referring to FIG. 3, the antireflection layer 202 can include two first-type insulating layers 202a and two second-type insulating layers 202b. In one embodiment, the number of the first-type insulating layers 202a can be different from the number of the second-type insulating layers 202b. In embodiments, the first insulating layers 202a and the second insulating layers 202b can be alternately stacked in the antireflection layer 202. The first-type insulating layers 202a can have a larger refractive index than that of the second-type insulating layers 202b.

A difference in the refractive index between the first-type insulating layers 202a and the second-type insulating layers 202b can range from 0.5 to 0.7. In a specific embodiment, the refractive index of the first-type insulating layers 202a can range from 2.0 to 2.25, and the refractive index of the second-type insulating layers 202b can range from 1.45 to 1.55.

In one embodiment, the first-type insulating layers 202a can be formed of silicon nitride and the second-type insulating layers 202b can be formed of silicon oxide.

In another embodiment, the first-type insulating layers 202a can be formed of titanium oxide (TiO) or zinc oxide (ZnO). In a specific embodiment, the first-type insulating layers 202a can have a refractive index of approximately 2.0.

Hereinafter, the relationship between the thickness and the reflectance of the antireflection layer 202 will be described with reference to experimental results.

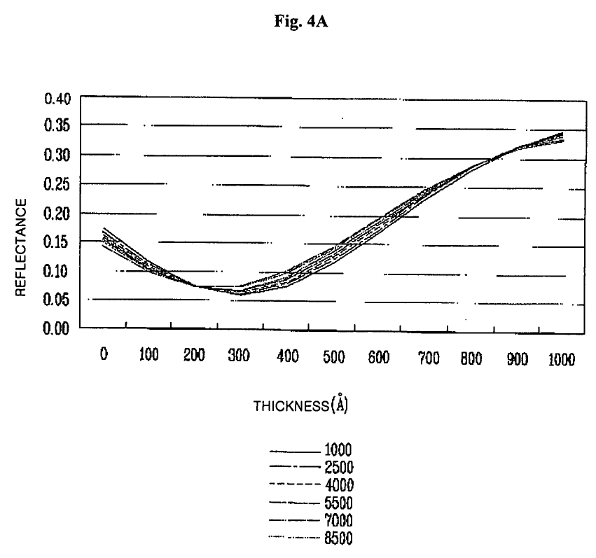

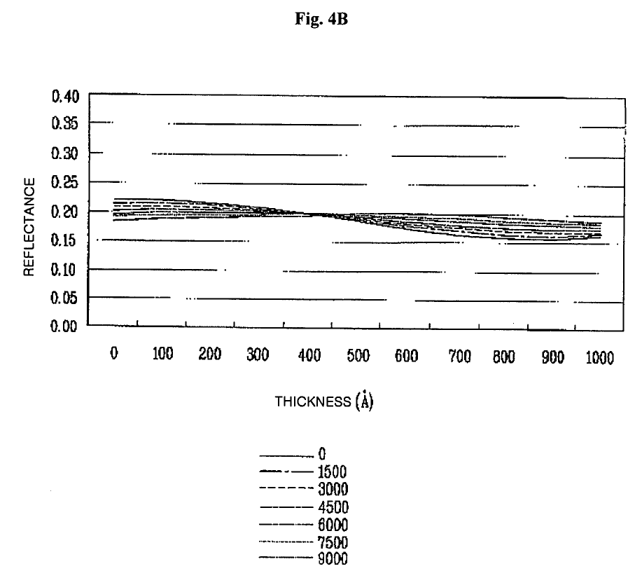

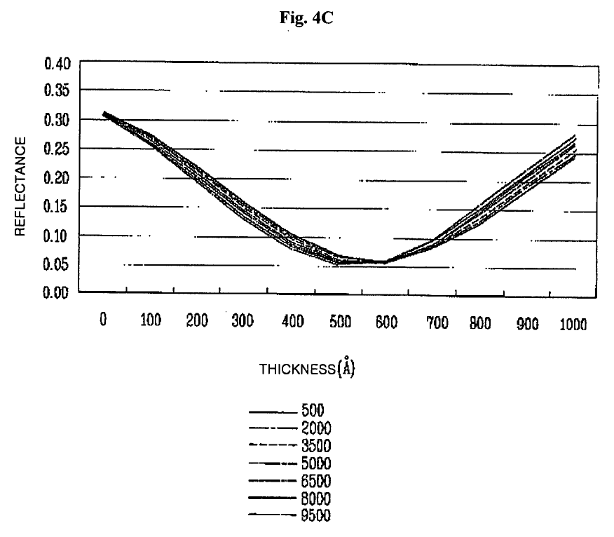

FIGS. 4A to 4C are graphs showing reflectance based on the thickness of the antireflection layer.

The experimental results are based on a device incorporating an antireflection layer having two first-type insulating layers 202a and one second-type insulating layer 202b. FIGS. 4A to 4C show a change in the reflectance of the antireflection layer when a thickness of the second-type insulating layer 202b is maintained constant and thicknesses of the first-type insulating layers are varied.

FIG. 4A shows a change in the reflectance of the antireflection layer when the thickness of the second-type insulating layer 202b is maintained constant, the thickness of the first-type insulating layer 202a formed under the second-type insulating layer 202b is varied from 0 to 1000 Å, and the thickness of the first-type insulating layer 202a formed on the second-type insulating layer 202b is varied to 1000, 2500, 4000, 5500, 7000, and 8500 Å, respectively.

FIG. 4B shows a change in the reflectance of the antireflection layer when the thickness of the second-type insulating layer 202b is maintained constant, the thickness of the first-type insulating layer 202a formed under the second-type insulating layer 202b is varied from 0 to 1000 Å, and the thickness of the first-type insulating layer 202a formed on the second-type insulating layer 202b is varied to 0, 1500, 3000, 4500, 6000, 7500, and 9000 Å, respectively.

FIG. 4C shows a change in the reflectance of the antireflection layer when the thickness of the second-type insulating layer 202b is maintained constant, the thickness of the first-type insulating layer 202a formed under the second-type insulating layer 202b is varied from 0 to 1000 Å, and the thickness of the first-type insulating layer 202a formed on the second-type insulating layer 202b is varied to 500, 2000, 3500, 5000, 6500, 8000, and 9500 Å, respectively.

Referring to FIGS. 4A to 4C, when the thickness of the first insulating layer 202a formed under the second insulating layer 202b ranges approximately from 200 to 400 Å, the antireflection layer has the lowest reflectance. That is, when the first insulating layer 202a formed under the second insulating layer 202b is formed of a thickness of approximately 200 to 400 Å, the antireflection layer 202 can have the highest transmittance.

In the image sensor of the aforementioned structure, light passing through the objective lens 206 and the plurality of microlenses 205 can be provided to the photodiodes 201 of the cell regions through the antireflection layer 202 almost without a loss.

Specifically, for light passing through the objective lens 206 incident onto the plurality of microlenses 205, the light is incident onto the microlens 205 located at the central portion of the image sensor at an angle of approximately 90°. Therefore, the light passing through the microlens 205 of the central portion is incident almost perpendicularly to the antireflection layer 202. Thus the light is substantially non-reflected and passes through the antireflection layer 202 to be provided to the photodiodes 201. That is, the light passing through the microlens 205 of the central portion can be provided to the photodiodes 201 almost without a loss,

Meanwhile, for light incident onto the microlens 205 far from the central portion of the image sensor, the light is incident at an acute angle. In particular, the farther from the central portion the microlens is, the smaller incident angle is. For example, light incident onto the microlens 205 located at an edge portion of the image sensor can be incident at an angle of approximately 30°. Here, the light passing through the microlens 205 located at the edge portion of the image sensor reaches the antireflection layer 202 formed thereunder. At this point, as the light passes through the first-type insulating layers 202a and the second-type insulating layer(s) 202b of the antireflection layer 202, the reflectance thereof is remarkably decreased. Accordingly, the light can be provided to the photodiodes 201 located at the edge portion of the image sensor almost without a loss.

Hereinafter, a method of fabricating an image sensor of the present invention will now be described in detail.

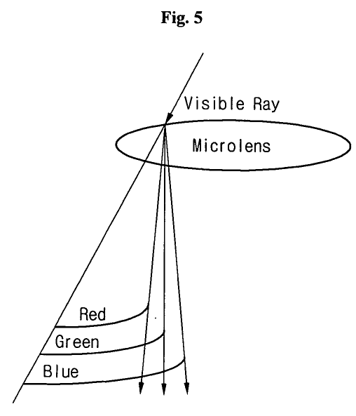

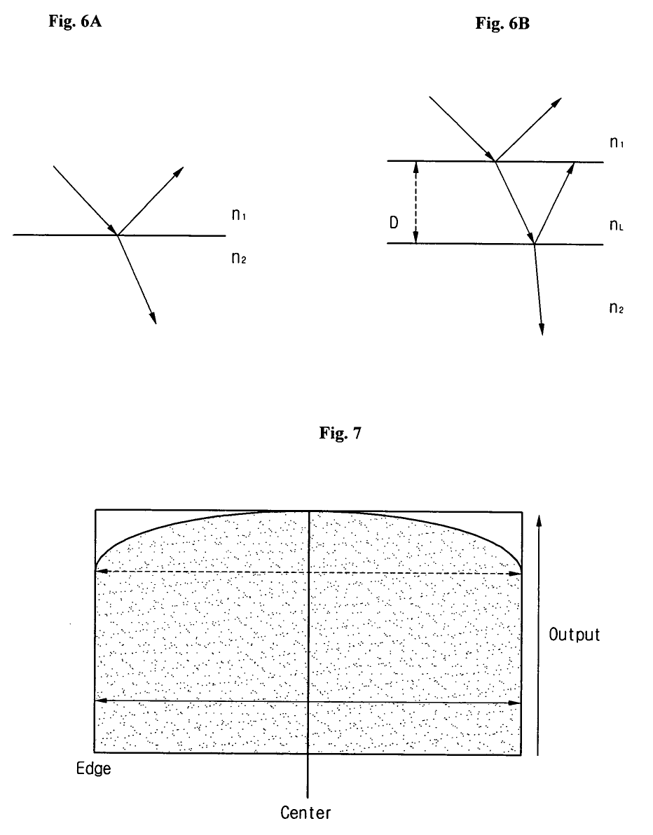

FIG. 5 is a view showing a difference in the refractive index depending on the wavelength of light incident to a microlens. FIGS. 6A and 6B are views showing refraction and reflection. FIG. 7 is a view showing an output difference based on the location of a microlens and corresponding photodiode(s) with respect to an objective lens.

As shown in FIG. 5, a difference in a refractive index occurs depending on the ranges of red, green, and blue wavelengths of visible rays incident to a microlens.

Referring to FIG. 6A, for a ray of light traveling through a first medium with a refractive index of n₁ and a second medium with a refractive index of n₂, the reflectance at normal incidence is given by:

$$R = {[ \frac{( {n}_{1} - {n}_{2} )}{( {n}_{1} + {n}_{2} )} ]}^{2}$$

Referring to FIG. 6B, for a ray of light traveling through a first medium with a refractive index of n₁, a middle medium (such as a microlens) with a refractive index of n_{L}, and a second medium with a refractive index of n₂, the reflectance at normal incidence is given by:

$$R = {[ \frac{( {n}_{L}^{2} - {n}_{1} {n}_{2} )}{( {n}_{L}^{2} + {n}_{1} {n}_{2} )} ]}^{2}$$

Therefore, in order to obtain a good degree of destructive interference between reflected waves, the refractive index n_{L} is given by:

$${n}_{L} = \sqrt{{n}_{1} {n}_{2}} ,$$

and the thickness of the middle medium is given by:

$$D = \frac{λ}{4 {n}_{L}}$$

FIG. 7 shows the image output of an image sensor based on the position of an image output region of an image sensor. In particular, an output in a central portion of the image output region is higher than that in the edge portions.

As shown above, the amount of light incident the image sensor at the central portion and the edges (the output difference) can be set by the incident angle and the refractive index of a medium depending on a wavelength of light.

For example, the thickness of a medium can be adjusted to control a reflectance in a long wavelength range having a relatively low refractive index.

Where the output difference is caused by a difference in the refractive index according to an incident angle of light in a long wavelength range such as a red light, the output difference can be controlled by adjusting the thickness of a medium such that the reflectance in the central portion of an image sensor can be higher than that in the edge portions.

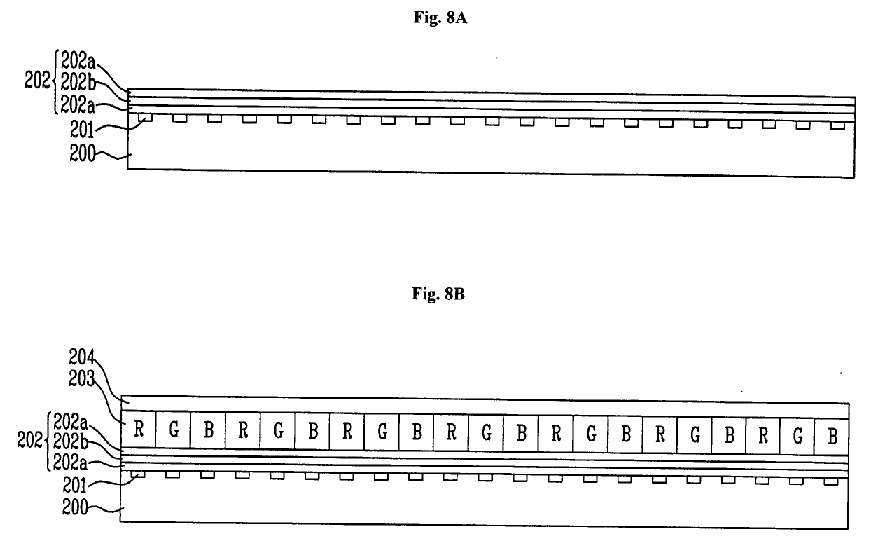

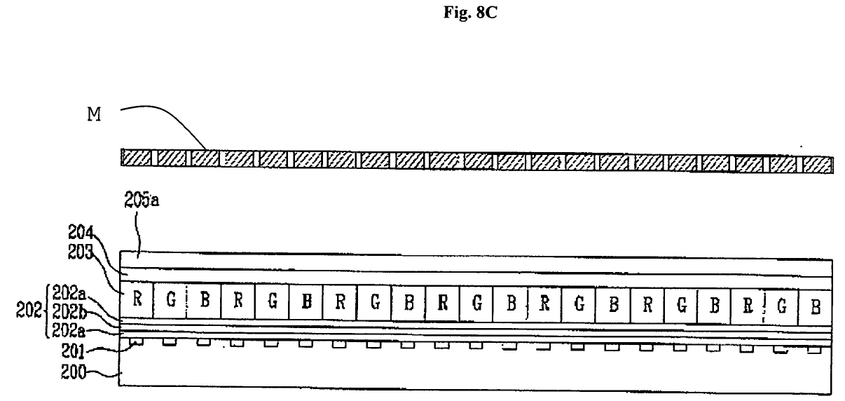

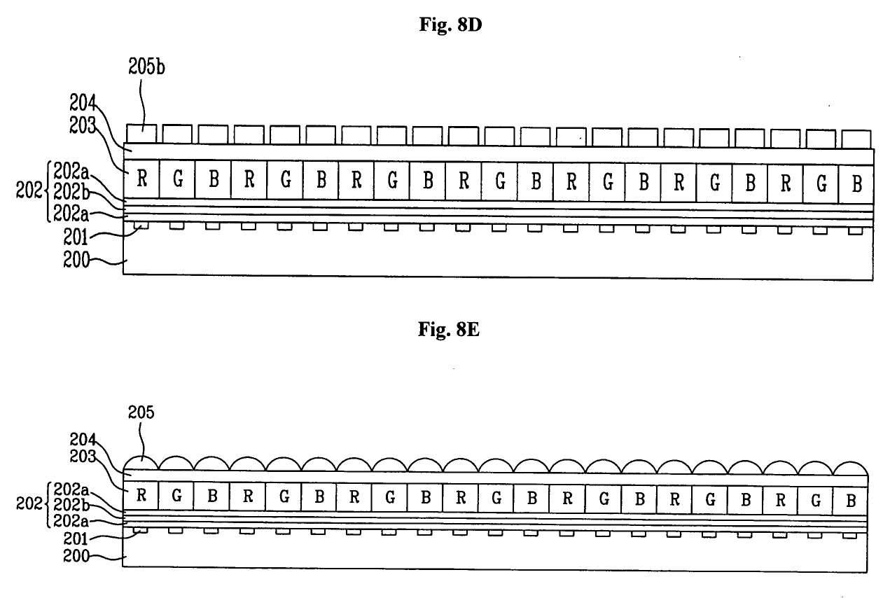

FIGS. 8A to 8E are sectional views showing a method of forming an image sensor according to an embodiment of the present invention.

Referring to FIG. 8A, a first-type insulating layer 202a can be formed on a semiconductor substrate in which a plurality of light detecting devices such as photodiodes 201 are formed. Next, a second-type insulating layer 202b having a different refractive index from that of the first-type insulating layer 202a can be formed on the first-type insulating layer 202a. Next, another first-type insulating layer 202a can be formed on the second-type insulating layer 202b. Consequently, an antireflection layer 202 including the first-type and second-type insulating layers 202a and 202b with different refractive indexes is formed on the semiconductor substrate 200.

In a specific embodiment, the first-type insulating layers 202a can be formed of silicon nitride and the second-type insulating layer 202b can be formed of silicon oxide.

Referring to FIG. 8B, a dye resist can be applied on the antireflection layer 202. Then, a color filter layer 203 for filtering different wavelength ranges of light can be formed by exposing and developing the dye resist.

A planarization layer 204 can be formed by depositing a silicon nitride layer on an entire surface of the semiconductor substrate 200 including the color filter layer 203. The planarization layer 204 can enhance the reliability of the image sensor, prevent an epoxy mold compound (EMC) from penetrating during a packaging process, and prevent moisture or heavy metal of the outside from penetrating.

Referring to FIG. 8C, a resist layer 205a for microlenses can be applied on the planarization layer 204. Then a reticle (M) having openings therein can be aligned above the resist layer 205a.

Next, light can be irradiated on the reticle (M) to selectively expose the resist layer 205a to light such that exposed portions of the resist layer 205a correspond to the openings of the reticle (M). In one embodiment, a laser can be used for irradiating.

Referring to FIG. 8D, the exposed resist layer 205a can be developed to form microlens patterns 205b.

Referring to FIG. 8E, the microlens patterns 205b can be reflowed at a predetermined temperature to form microlenses 205.

The image sensor according to the present invention has the following advantages.

The antireflection layer can be formed between the semiconductor substrate and the color filter layer of the image sensor to decrease the reflectance of light. The antireflection layer can include at least two insulating layers with different refractive indexes. Therefore, the image sensor of the present invention can minimize a light loss by decreasing the reflectance of light incident to both edge portions of the image sensor at a small angle.

It will be apparent to those skilled in the art that various modifications and variations can be made in the present invention. Thus, it is intended that the present invention covers the modifications and variations of this invention provided they come within the scope of the appended claims and their equivalents.

I claim:

1. An image sensor comprising:
a substrate having a plurality of cell regions;
photodiodes formed in the cell regions of the substrate;
an antireflection layer formed above the substrate including the photodiodes, wherein the antireflection layer includes at least two insulating layer types with different refractive indexes, respectively;
a color filter layer formed on the antireflection layer corresponding to the photodiodes;
a planarization layer formed on the color filter layer; and
a plurality of microlenses formed on the planarization layer corresponding to the photodiodes.

2. The image sensor according to claim 1, wherein the antireflection layer comprises:
a first-type insulating layer formed on the substrate including the photodiodes;
a second-type insulating layer formed on the first-type insulating layer and having a smaller refractive index than a refractive index of the first insulating layer; and
another first-type insulating layer formed on the second-type insulating layer.

3. The image sensor according to claim 2, wherein a difference in the refractive index between the first-type insulating layer and the second-type insulating layer ranges from 0.5 to 0.7.

4. The image sensor according to claim 2, wherein the first-type insulating layers are formed of SiNₓ (silicon nitride) and the second-type insulating layer is formed of SiOₓ (silicon oxide).

5. The image sensor according to claim 2, wherein the first-type insulating layers are formed of TiO (titanium oxide) or ZnO (zinc oxide).

6. The image sensor according to claim 1, further comprising an objective lens disposed above the microlenses, wherein the objective lens condenses light from an outside source and provides the condensed light to the microlenses.

7. The image sensor according to claim 1, wherein a reflectance is controlled by adjusting a thickness of the microlenses depending on a wavelength of incident light.

8. A method of fabricating an image sensor, the method comprising:
providing a substrate including photodiodes;
forming an antireflection layer above the substrate including photodiodes, wherein the antireflection layer includes at least two insulating layer types with different refractive indexes, respectively;
forming a color filter layer on the antireflection layer corresponding to the photodiodes;
forming a planarization layer on the color filter layer; and
forming a plurality of microlenses on the planarization layer corresponding to the photodiodes.

9. The method according to claim 8, wherein forming an antireflection layer comprises:
forming a first-type insulating layer on the substrate including photodiodes;
forming a second-type insulating layer on the first-type insulating layer; and
forming another first-type insulating layer on the second-type insulating layer.

10. The method according to claim 8, wherein the first-type insulating layers are formed of SiNₓ (silicon nitride) and the second-type insulating layer is formed of SiOₓ (silicon oxide).

11. The method according to claim 8, wherein the first-type insulating layers are formed of TiO (titanium oxide) or ZnO (zinc oxide).

12. The method according to claim 8, wherein a difference in the refractive index between the first-type insulating layers and the second-type insulating layer ranges from 0.5 to 0.7.

13. The method according to claim 8, further comprising adjusting a thickness of the microlenses depending on a wavelength of incident light to control reflectance.
